(19) United States
(12) Patent Application Publication
(10) Pub. No.: US 2025/0391640 A1
(43) Pub. Date: Dec. 25, 2025

(54) IMPEDANCE MATCHING CIRCUIT FOR A PLASMA PROCESS SYSTEM AND A PLASMA PROCESS SYSTEM COMPRISING AN IMPEDANCE MATCHING CIRCUIT OF THIS TYPE

(71) Applicant: TRUMPF HÜTTINGER GMBH + CO. KG, Freiburg (DE)

(72) Inventor: Birger NORDMANN, Herdecke (DE)

(21) Appl. No.: 19/310,958

(22) Filed: Aug. 27, 2025

Related U.S. Application Data
(63) Continuation of application No. PCT/EP2024/054979, filed on Feb. 27, 2024.

(30) Foreign Application Priority Data
Feb. 28, 2023 (DE) 10 2023 104 955.0

(51) Int. Cl. H01J 37/32

(52) U.S. Cl. CPC H01J 37/32183

(57) ABSTRACT

An impedance matching circuit for a plasma process system, for powers ≥500 W and frequencies in the range from 2 MHz to 100 MHz, wherein the impedance matching circuit is configured for a predetermined rated power. The impedance matching circuit including an input terminal, an output terminal, and a first, second, and third impedance matching unit. The output terminal is configured to electrically connect the impedance matching circuit to a consumer in the form of a plasma process chamber. A conductance and resistance of the first intermediate impedance is greater than a conductance and resistance, respectively, of the impedance that would arise at the input of the second impedance matching unit at the rated power of the impedance matching circuit and the maximum permissible voltage and current, respectively, of the at least one semiconductor switching element.

### CROSS REFERENCE TO RELATED APPLICATIONS

This application is a continuation of International Application No. PCT/EP2024/054979 (WO 2024/180075 A1), filed on Feb. 27, 2024, and claims benefit to German Patent Application No. DE 10 2023 104 955.0, filed on Feb. 28, 2023. The aforementioned applications are hereby incorporated by reference herein.

### FIELD

The present disclosure relates to an impedance matching circuit and to a plasma process system having an impedance matching circuit.

### BACKGROUND

The surface treatment of workpieces using plasma and gas lasers are industrial processes in which, in particular in a plasma process chamber, a plasma is generated either using direct current or a high-frequency alternating signal having an operating frequency in the range of several tens of kHz up to the GHz range, in particular up to 10 GHz.

The plasma process chamber is connected to a high-frequency power supply via additional electronic components such as coils, capacitors, cables or transformers. These additional components can be resonant circuits, filters or impedance matching circuits.

‘High frequency’ is also abbreviated to ‘HF’ in the following. HF here refers to frequencies in the range from 2 MHz to 100 MHz, in particular in the range from 10 MHz to 50 MHz.

The plasma process has the problem that the electrical load impedance of the plasma process chamber, which occurs during the process and is caused by the plasma, which is to be regarded here as an electrical load or consumer, depends on the conditions in the plasma process chamber and can vary greatly. In particular, the properties of the workpiece, electrodes and gas conditions are taken into account.

HF power supplies have a limited operating range with respect to the impedance of the connected electrical load, also called the “consumer”. If the load impedance leaves a permissible range, the HF power supply may be damaged or even destroyed.

For this reason, an impedance matching circuit, also called a matchbox, is usually required to transform the impedance of the load to a nominal impedance of the HF power supply output.

Different impedance matching circuits are known. The impedance matching circuits can be fixed and have a predetermined transformation effect, i.e., they consist of electrical components, in particular coils and capacitors, which are not changed during operation. This is particularly useful for operations that are always consistent, such as with a gas laser. Furthermore, impedance matching circuits are known in which at least some of the components of the impedance matching circuits can be changed, in particular by mechanically changing the components. For example, motor-driven rotary capacitors are known, the capacitance value of which can be changed by changing the arrangement of the capacitor plates relative to one another.

A plasma can, in a general sense, be assigned to three impedance ranges. In the unignited state, very high impedances are present. In normal operation, i.e., when used as intended with plasma, lower impedances are present. Very small impedances can occur in the case of unwanted local discharges, also called “arcs”, or plasma fluctuations. In addition to these three identified impedance ranges, other special conditions with other associated impedance values can occur. If the load impedance changes suddenly and the load impedance or the transformed load impedance moves out of a permissible impedance range, the HF power supply or transmission devices between the HF power supply and the plasma process chamber may be damaged. There are also stable states of the plasma that are not desired.

In order to adapt the usually fixed output impedance of an HF power supply to the changing electrical load, an impedance matching circuit is usually provided directly upstream of the load. Such an impedance matching circuit is described for example in the document DE 10 2009 001 355 A1.

Impedance matching circuits whose electrical properties, such as their capacitances, can be changed during operation, for example, have motors to change these electrical properties. However, there are also impedance matching circuits that use semiconductor switches to switch capacitors on and off. The problem here is that, depending on the load condition, the current and voltage carrying capacity of the semiconductor switches is insufficient. The current and voltage carrying capacity of the actual semiconductor switches determines the maximum transferable power of such an impedance matching circuit. Neither the impedances in a 50-ohm system nor those directly at the plasma process chamber are suitable to exploit both the current and voltage limits of a semiconductor switching element across two switching positions. In principle, it can be stated that the semiconductor switching elements are not switched within their optimal range.

Either the current and/or voltage are too low, so that the semiconductor switching elements are not fully controlled, or the current and voltage are so high that the semiconductor switching elements can be damaged. The latter case is to be avoided, so that the semiconductor switches provided in the prior art are never fully utilized.

### SUMMARY

In an embodiment, the present disclosure provides an impedance matching circuit for a plasma process system, for powers ≥500 W and frequencies in the range from 2 MHz to 100 MHz, wherein the impedance matching circuit is configured for a predetermined rated power. The impedance matching circuit comprises an input terminal, an output terminal, and a first, second, and third impedance matching unit. The output terminal is configured to electrically connect the impedance matching circuit to a consumer in the form of a plasma process chamber. A conductance and resistance of the first intermediate impedance is greater than a conductance and resistance, respectively, of the impedance that would arise at the input of the second impedance matching unit at the rated power of the impedance matching circuit and the maximum permissible voltage and current, respectively, of the at least one semiconductor switching element.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates an embodiment of a plasma process system according to the present disclosure having an impedance matching circuit according to the present disclosure;

FIG. 2A and FIG. 2B illustrate various embodiments of how a first impedance matching unit of the impedance matching circuit can be constructed;

FIG. 3A, FIG. 3B, FIG. 3C, FIG. 3D, FIG. 3E and FIG. 3F illustrate various embodiments of how a second impedance matching unit of the impedance matching circuit can be constructed;

FIG. 4A, FIG. 4B, FIG. 4C, FIG. 4D and FIG. 4E illustrate various embodiments of how a third impedance matching unit of the impedance matching circuit can be constructed;

FIG. 5 illustrates an embodiment of a plasma process supply system; and

FIG. 6 illustrates part of a measuring unit of a plasma process system.

### DETAILED DESCRIPTION

In an embodiment of the present disclosure, an impedance matching circuit whose components are utilized more advantageously than in the prior art is provided.

The impedance matching circuit according to the present disclosure is used in particular in a plasma process system, wherein the impedance matching circuit is configured for a predetermined rated power. The impedance matching circuit comprises an input terminal which is configured to electrically, in particular galvanically, connect the impedance matching circuit to an HF power supply. The impedance matching circuit is particularly configured for powers ≥500 W, preferably ≥2 kW and frequencies in the range from 2 MHz to 100 MHz. The impedance matching circuit also comprises an output terminal which is configured to electrically, preferably galvanically, connect the impedance matching circuit to a consumer, in particular in the form of a plasma process chamber. The impedance matching circuit comprises a first impedance matching unit which is electrically connected to the input terminal and which is configured to transform the input impedance at the input terminal to a first intermediate impedance, wherein the transformation ratio cannot be changed during operation. The input impedance is preferably 50 ohms and thus also preferably around the nominal impedance of the HF power supply. The wording that the “transformation ratio cannot be changed during operation” means that no automatic adjustment, e.g., by means of a motor or semiconductor switch, of capacitance values and/or inductance values is possible during operation. The impedance matching circuit further comprises a second impedance matching unit having at least one semiconductor switching element. The second impedance matching unit comprises an input and is electrically connected via this input to the output of the first impedance matching unit. The second impedance matching unit is configured to transform the first intermediate impedance at its input to a second intermediate impedance at its output, wherein the transformation ratio can be changed during operation by the at least one semiconductor switching element. The impedance matching circuit further comprises a third impedance matching unit which is electrically connected to the output of the second impedance matching unit. An output of the third impedance matching unit is electrically connected to the output terminal of the impedance matching circuit. The third impedance matching unit is configured to transform the second intermediate impedance to an output impedance provided at the output terminal. The at least one semiconductor switching element of the impedance matching unit can thus be operated up to a maximum permissible voltage and up to a maximum permissible current. These values can be taken, for example, from the corresponding data sheet of the semiconductor switching element used. The first intermediate impedance, to which the first impedance matching unit transforms the input impedance, is selected for a predetermined target input impedance such that:
a) the conductance of the first intermediate impedance is greater than the conductance of the impedance that would arise at the input of the second impedance matching unit at the rated power of the impedance matching circuit and the maximum permissible voltage of the at least one semiconductor switching element; and
b) the resistance of the first intermediate impedance is greater than the resistance of the impedance that would arise at the input of the second impedance matching unit at the rated power of the impedance matching circuit and the maximum permissible current of the at least one semiconductor switching element.

The dimensioning according to the present disclosure of the impedance matching circuit, which was determined by calculations, simulations, circuit design, tests and investigations, ensures that the at least one semiconductor switching element is fully utilized, but is not overloaded. This is especially the case for such an impedance matching circuit configured for power of greater than or equal to 2 kW, since the voltages and currents overload the conventional semiconductor switching elements in this power range. It was thus determined that the impedance matching unit should meet the above-mentioned criteria with regard to the transformation of the input impedance to a first intermediate impedance, wherein the input impedance is preferably constant and, more preferably, corresponds to 50 ohms. This and the maximum permissible voltage and maximum permissible current of the semiconductor switching element allow the transformation ratio set by the first impedance matching unit to be accurately calculated. The at least one semiconductor switching element is not overloaded, but switches currents and voltages that are preferably below the maximum permissible values. This means that at least one semiconductor switching element is fully controlled, which in turn means that the semiconductor switching element does not have to be oversized, which in turn saves costs. The dimensioning rule ensures that no critical situations arise with regard to the current and voltage resistance of at least one semiconductor switching element. In the impedance matching circuit according to the present disclosure, it is particularly possible to dispense with connecting a plurality of semiconductor switching elements in parallel and/or in series with one another. This is advantageous because the effort required to actually switch the plurality of semiconductor switching elements at the same time is very high. If one semiconductor switching element switches slightly later than the other semiconductor switching elements, the impedance matching circuit may be destroyed. However, this is successfully avoided by the dimensioning according to the present disclosure. The dimensioning can thus ensure that, with a defined input impedance, which is specified in particular by the HF power supply, no operating situation arises for the at least one semiconductor switching element in which the at least one semiconductor switching element could be destroyed. The at least one semiconductor switching element only has to switch currents and/or voltages that are below the maximum permissible voltage and/or the maximum permissible current. An additional control loop to measure voltages and/or currents and to make the switching behavior dependent on them is therefore not necessary. As a result, the semiconductor switching element does not have to be significantly oversized as in impedance matching circuits known from the prior art, which makes the impedance matching circuit according to the present disclosure cheaper to manufacture.

For the term “conductance” of a complex impedance Z, it shall generally apply that the conductance is real and equal to G, with the following relationship:

$$\underline{Z} = 1 / \underline{Y} = 1 / ( G + jB ) .$$

Consequently, the conductance of the first intermediate impedance Z₁ is defined as G₁,
wherein the following applies: Z₁=1/Y₁=1/(G₁+jB₁).

B, B₁ are, in each case, the imaginary part of the complex conductance Y, Y₁ respectively.

For the term “resistance” of a complex impedance Z, it shall generally apply that the resistance is real and equal to R, with the following relationship: Z=R+jX.

The resistance of the first intermediate impedance is therefore R₁ wherein the following applies:

$$\underline{Z} 1 = R 1 + j X 1 .$$

X, X₁ are, in each case, the imaginary part of the complex impedance Z, Z₁, respectively.

In an embodiment of the impedance matching circuit, the first intermediate impedance is selected such that:

$${G}_{1} > {P}_{r a t e d} / {U}_{max}^{2} ,$$

with
G₁=conductance of the first intermediate impedance;
P_{rated}=rated power of the impedance matching circuit;
Uₘₐₓ=maximum voltage at the at least one semiconductor switching element;
and

$${R}_{1} > {P}_{rated} / {I}_{max}^{2} ,$$

with
R₁=resistance of the first intermediate impedance;
P_{rated}=rated power of the impedance matching circuit;
Iₘₐₓ=maximum current at the at least one semiconductor switching element.

This allows the dimensions to be adjusted even more precisely.

In an embodiment of the impedance matching circuit, in one of the two switching states of the at least one semiconductor switching element, a voltage or a current is applied to the semiconductor switching element that is less than 20%, in particular less than 10%, away from the maximum permissible values for voltage or current.

In an embodiment of the impedance matching circuit, the input impedance remains substantially constant during operation of the impedance matching circuit and is equal to the predetermined target input impedance. On the one hand, this presents a constant impedance to the HF power supply and, on the other hand, the constant transformation ratio from the input impedance to the first intermediate impedance by the first impedance matching unit ensures that the at least one semiconductor switching element is always operated within the tolerances and at the same time with a high level of modulation.

In an embodiment of the impedance matching circuit, the first intermediate impedance is closer on the Smith chart to the output impedance than to the input impedance. Additionally or alternatively, the second intermediate impedance is closer on the Smith chart to the output impedance than to the first intermediate impedance. This ensures that the control of the at least one semiconductor switching element can be maximized.

In an embodiment of the impedance matching circuit, the at least one semiconductor switching element of the second impedance matching unit is a transistor or a diode. This allows the transformation ratio to be changed particularly quickly during operation.

A transistor can be configured as a metal-oxide-semiconductor field-effect transistor (MOSFET). A switching diode can, for example, be configured as a PIN diode.

In an embodiment, the output impedance can be determined by the consumer, in particular in the form of the plasma process chamber, and can be changed during operation. The output impedance can lie within a certain range on the Smith chart. The at least one semiconductor switching element assumes different switching states for those points of the output impedance that lie furthest apart within the specified range on the Smith chart. The “specified range” can also be defined as the permissible range in which the consumer can be operated. This “specified range” can be defined in advance.

In an embodiment, the transformation ratio of the third impedance matching unit cannot be changed during operation.

In an embodiment, the impedance matching unit comprises at least one motor-adjustable capacitor, whereby the transformation ratio of the third impedance matching unit can be changed during operation. This allows for even more precise response to changing output impedance from the consumer during operation.

In an embodiment, the second intermediate impedance, to which the second impedance matching unit transforms the first intermediate impedance, is selected such that:
a) the conductance of the second intermediate impedance is greater than the conductance of the impedance that would arise at the rated power of the impedance matching circuit and the maximum voltage at the at least one motor-adjustable capacitor; and
b) the resistance of the second intermediate impedance is greater than the resistance of the impedance that would arise at the rated power of the impedance matching circuit and the maximum current at the at least one motor-adjustable capacitor.

This also ensures that the motor-adjustable capacitor of the third impedance matching unit is fully controlled, while at the same time the maximum permissible values for current and voltage are not exceeded. In this case, the motor-adjustable capacitor does not need to be oversized, which optimizes the costs for the third impedance matching unit.

The conductance of the second intermediate impedance Z₂ is G₂,
wherein the following applies: Z₂=1/Y₂=1/(G₂+jB₂).

The resistance of the second intermediate impedance is R₂ wherein the following applies:

$${\underline{Z}}_{2} = {R}_{2} + j {X}_{2} .$$

In an embodiment of the impedance matching circuit, the second intermediate impedance is selected such that:

$${G}_{2} > {P}_{rated} / {U}_{max}^{2} ,$$

with
G₂=conductance of the second intermediate impedance;
P_{rated}=rated power of the impedance matching circuit;
Uₘₐₓ=maximum voltage of the at least one motor-adjustable capacitor; and

$${R}_{2} > {P}_{r a t e d} / {I}_{max}^{2} ,$$

with
R₂=resistance of the second intermediate impedance;
P_{rated}=rated power of the impedance matching circuit;
Iₘₐₓ=maximum current at the at least one motor-adjustable capacitor.

In an embodiment of the impedance matching circuit, the third impedance matching unit is free of a semiconductor switching element. This offers particular advantages when there is a high impedance change caused by the consumer. This also applies if the capacitor of the third impedance matching unit is motor-adjustable. Such a “motor-adjustable capacitor” is not to be understood, in particular, as a stepwise switching-in or switching-out of capacitances, but rather as merely the adjustment of a distance between two plates of a plate capacitor, thereby changing its capacitance.

In an embodiment, the first impedance matching unit comprises an output, at least one coil and at least one first capacitor, each of which is configured as a discrete component. The at least one coil connects the input terminal of the impedance matching circuit to a reference ground. The at least one first capacitor connects the input terminal of the impedance matching circuit to the output at which the first intermediate impedance is present. Such a structure is particularly suitable for frequencies from 2 MHz to 50 MHz, in particular in the range from 10 MHz to 30 MHz, particularly preferably at approximately 13 MHz.

In an embodiment, the first impedance matching unit comprises at least one second capacitor, which is configured in particular as a discrete component. The at least one second capacitor connects the output of the first impedance matching unit to the reference ground. Such a structure is particularly suitable for frequencies from 2 MHz to 50 MHz, in particular in the range from 10 MHz to 30 MHz, particularly preferably at approximately 27 MHz.

In an embodiment, the second impedance matching unit comprises at least one coil, at least one first capacitor and at least one further capacitor, each of which is configured as a discrete component. The first intermediate impedance is present at an input of the second impedance matching unit. The second intermediate impedance is present at an output of the second impedance matching unit. The at least one coil is arranged in a transmission path connecting the input to the output. The at least one semiconductor switching element is configured to effectively electrically connect the transmission path to a reference ground via the at least one first capacitor and/or to effectively connect the at least one further capacitor in series in the transmission path.

In an embodiment, the second impedance matching unit comprises a multitude of semiconductor switching elements and a multitude of capacitors. The multitude of semiconductor switching elements are configured:
a) to electrically connect the transmission path to a reference ground via each of the capacitors, wherein a semiconductor switching element is arranged in series with each capacitor and wherein each capacitor with its respective semiconductor switching element is arranged in parallel with the other capacitors with their respective semiconductor switching elements, whereby a multitude of transformation ratios can be set; and/or
b) to effectively connect at least one capacitor and/or coil to the transmission path, wherein one semiconductor switching element is arranged in series with or parallel to the each capacitor or coil. This allows the transformation ratio to be changed in a very efficient way during operation.

In an embodiment, the third impedance matching unit comprises at least one coil and at least one capacitor, each of which is configured as a discrete component. The third impedance matching unit comprises an input, the output terminal and a transmission path, wherein the transmission path electrically connects the input to the output terminal. The second intermediate impedance is present at the input. The at least one coil connects the transmission path to the reference ground.

In an embodiment, the at least one coil of the third impedance matching unit is connected to the input directly or via the at least one capacitor of the third impedance matching unit. Additionally or alternatively, the at least one coil of the third impedance matching unit is connected to the output terminal directly or via the at least one capacitor and/or a further coil. Such a configuration has yielded very good results in practice.

In an embodiment, the at least one semiconductor switching element can be cooled by a fluid. The fluid can be, for example, water. This also includes distilled water.

The plasma process system according to the present disclosure comprises an impedance matching circuit as described above. Furthermore, the plasma process system comprises an HF power supply and at least one consumer, in particular in the form of a plasma process chamber. The HF power supply is connected to the input terminal of the impedance matching circuit. The output terminal of the impedance matching circuit is connected to the at least one consumer. The input impedance of the impedance matching circuit corresponds to the nominal impedance of the HF power supply. Therefore, there is an adaptation and no or very little power is reflected back towards the HF power supply. Due to the dimensioning rule for the first intermediate impedance described above, the maximum permissible voltage and the maximum permissible current at the at least one semiconductor switching element are not exceeded.

In an embodiment, the plasma process system comprises a measuring unit arranged between the HF power supply and the impedance matching circuit. The measuring unit comprises a directional coupler or a sensor pair comprising a current sensor and a voltage sensor. A control and/or detection device is also provided, wherein the control and/or detection device is configured to receive measured values, such as a power transmitted into the impedance matching circuit, from the measuring unit. Additionally or alternatively, power reflected by the impedance matching circuit can also be received by the measuring unit. These measured values describe the input variables present at the input terminal of the impedance matching circuit. The control and/or detection device is configured to control the at least one semiconductor switching element on the basis of the measured values in such a way that the plasma is generated in the plasma process chamber in the desired form.

Embodiments of the present disclosure are described below by way of example with reference to the drawings.

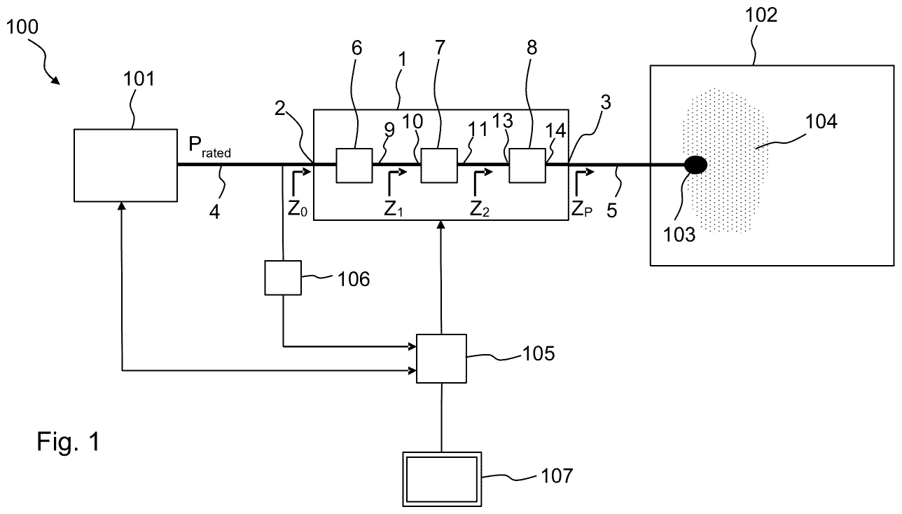

FIG. 1 shows a plasma process system 100 which comprises an impedance matching circuit 1. The plasma process system 100 further comprises an HF power supply 101 and at least one consumer 102 in the form of a plasma process chamber. The HF power supply 101 is configured to supply an HF signal, in particular in the form of a uniform signal, also called a continuous wave signal, or CW signal for short, with a rated power P_{rated}. The impedance matching circuit 1 comprises an input terminal 2, wherein the HF power supply 101 is connected to the input terminal 2. The impedance matching circuit 1 further comprises an output terminal 3. The output terminal 3 is connected to the at least one consumer 102. The HF power supply 101 is preferably connected to the impedance matching circuit 1 via a first cable arrangement 4. The impedance matching circuit 1 is preferably connected to the consumer 102 via a second cable arrangement 5. The first and/or second cable arrangement 4, 5 can comprise one or a plurality of cables, for example connected in series and/or in parallel. Coaxial cables are preferably used.

The consumer 102, i.e., the plasma process chamber, comprises at least one electrode 103 for generating a plasma 104. The electrode 103 is connected, in particular galvanically, to the output terminal 3 of the impedance matching circuit 1.

The plasma process system 100 also comprises a control and/or detection device 105. This can preferably comprise a processor and/or a programmable logic component, in particular an FPGA and/or microcontroller and/or a preconfigured logic component, in particular an ASIC. The control and/or detection device 105 can also comprise a storage unit. The control and/or detection device 105 is configured to control the HF power supply 101, in particular to activate or deactivate it. Additionally or alternatively, the control and/or detection device 105 is also configured to change the power and/or frequency of the HF signal. Additionally or alternatively, the control and/or detection device 105 is configured to change the waveform of the HF signal, in particular the type of the HF signal or the modulation of the HF signal.

The control and/or detection device 105 is preferably also configured to control the impedance matching circuit 1. In particular, the control and/or detection device 105 is configured to change the transformation ratio within the impedance matching circuit 1.

The plasma process system 100 preferably also comprises a measuring unit 106. The measuring unit 106 is arranged between the HF power supply 101 and the impedance matching circuit 1. The measuring unit 106 can, for example, comprise at least one directional coupler or a combination consisting of a current sensor and a voltage sensor. Via the at least one directional coupler, the measuring unit 106 can measure the power of the HF signal which is transmitted from the HF power supply 101 towards the impedance matching circuit 1. Preferably, the measuring unit 106 can also measure the power of an HF signal which is reflected back at the impedance matching circuit 1 towards the HF power supply 101. The combination of a current sensor and a voltage sensor can also be used to determine the power of the HF signal that is transmitted from the HF power supply 101 towards the impedance matching circuit 1. A power of an HF signal reflected by the impedance matching circuit 1 can also be detected by the current sensor and/or the voltage sensor.

The plasma process system 100 preferably also comprises an operating unit 107. The operating unit 107 preferably has a screen, in particular a touch-sensitive screen. In addition to a screen, the operating unit 107 can also comprise input devices such as a keyboard and/or mouse. The operating unit 107 can also be a web server that provides data and receives user input. The control and/or detection device 105 is configured to display current settings of the HF power supply 101 and/or the impedance matching circuit 1 on the operating unit 107. The control and/or detection device 105 can also be configured to display the measured values received by the measuring unit 106 on the operating unit 107. The control and/or detection device 105 is preferably configured to receive setpoint specifications, for example for the power of the HF signal, the frequency of the HF signal and/or the waveform of the HF signal, from the operating unit 107 and to generate corresponding actuating variables for the HF power supply 101 and to transmit them thereto.

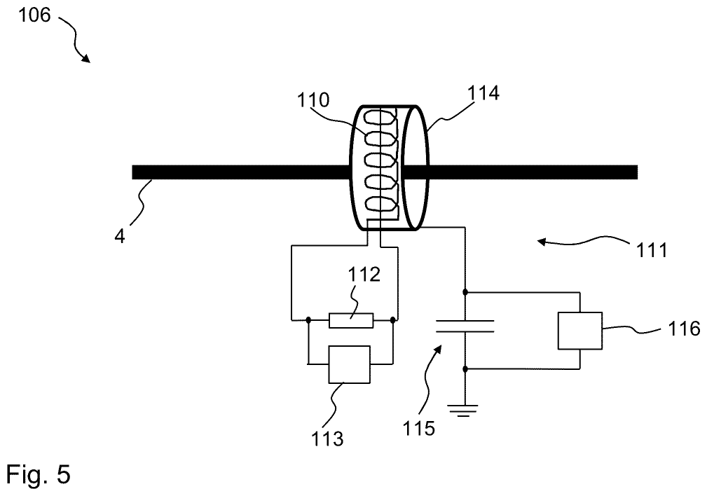

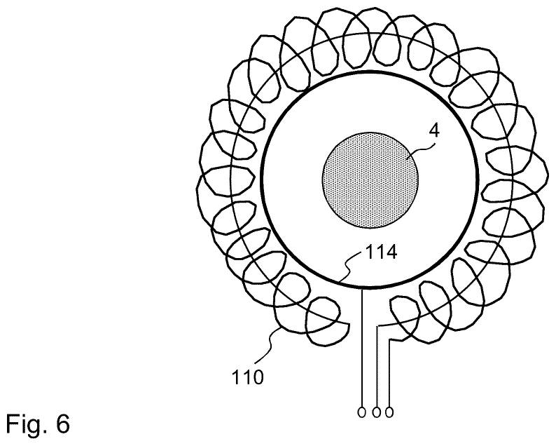

Before an impedance matching circuit 1 according to an embodiment of the present disclosure is explained in detail, reference is made to FIGS. 5 and 6, in each of which a measuring unit 106 is described. This can be the same measuring unit in two different views. In these exemplary embodiments, the measuring unit 106 is configured to contactlessly measure a voltage and a current. For this purpose, the measuring unit 106 comprises a current sensor 110 and a voltage sensor 111.

However, the phase relationship between current and voltage is still preferably determined and/or measured.

The current sensor 110 of the measuring unit 106 is a coil, in particular in the form of a Rogowski coil.

Both ends of the coil are preferably connected to each other via a shunt resistor 112. The voltage drop across the shunt resistor 112 can be digitized by means of a first A/D converter 113.

The voltage sensor 111 of the measuring unit 106 is preferably configured as a capacitive voltage divider. A first capacitor 114 is formed by an electrically conductive ring 114. An electrically conductive cylinder could also be used. The first cable arrangement 4 is guided through this electrically conductive ring 114. A second capacitor 115 of the voltage sensor 111, which is constructed as a voltage divider, is connected to the reference ground. A second A/D converter 116 is connected in parallel to the second capacitor 115 and is configured to detect and digitize the voltage dropped across the second capacitor 115.

In principle, the measuring unit 106 can also be arranged or constructed on a (common) printed circuit board. The first capacitor 114 can be formed by a coating on a first and an opposite second side of the circuit board. In this case, the coatings on the first and second sides are electrically connected to each other by vias. The first cable arrangement 4 is passed through an opening in the circuit board. The second capacitor 115 can be formed by a discrete component.

The current sensor 110 in the form of the coil, in particular in the form of the Rogowski coil, is spaced further from the first cable arrangement 4 than the first capacitor 114. The coil can also be formed on the same circuit board by appropriate coatings and vias. The coil for current measurement and the first capacitor for voltage measurement preferably run through a common plane.

The shunt resistor 112 can also be arranged on this circuit board. The same applies to the first and/or second A/D converter 113, 116. The first and/or second A/D converter 113, 116 is read and/or controlled by the control and/or detection device 105.

The control and/or detection device 105 is preferably configured to control the impedance matching circuit 1 on the basis of the measured values of the measuring unit 106.

In the following, reference is again made to FIG. 1 and the structure of the impedance matching circuit 1 is explained in more detail. The impedance matching circuit 1 comprises a first impedance matching unit 6, a second impedance matching unit 7 and a third impedance matching unit 8. The first impedance matching unit 6 is electrically connected to the input terminal 2.

The first impedance matching unit 6 is configured to transform an input impedance Z₀, which is present at the input terminal 2, into a first intermediate impedance Z₁. The first intermediate impedance Z₁ is present at an output 9 of the first impedance matching unit 6. The transformation ratio is cannot be changed during operation. The second impedance matching unit 7 is connected to the first impedance matching unit 6 in the transmission direction of the HF signal from the HF power supply 101 to the consumer 102. In particular, the second impedance matching unit 7 comprises an input 10 which is connected to the output 9 of the first impedance matching unit 6 or which is identical to the output 9. The first intermediate impedance Z₁ is therefore also present at the input 10. The second impedance matching unit 7 is configured to transform the first intermediate impedance Z₁ at its input 10 to a second intermediate impedance Z₂ at its output 11, wherein the transformation ratio can be changed by at least one semiconductor switching element 12 during operation. The third impedance matching unit 8 is connected to the second impedance matching unit 7 in the transmission direction of the HF signal from the HF power supply 101 to the consumer 102. In particular, the third impedance matching unit 8 comprises an input 13 which is connected to the output 11 of the second impedance matching unit 7 or which is identical to the output 11. The second intermediate impedance Z₂ is therefore also present at the input 13. The third impedance matching unit 8 is configured to transform the second intermediate impedance Z₂ at its input 13 to an output impedance Z_{P} at its output 14. The transformation ratio can or cannot be changed during operation. The output 14 of the third impedance matching unit 8 is electrically connected to the output terminal 3 of the impedance matching circuit 1. This also includes the possibility that the output 14 of the third impedance matching unit 8 is identical to the output terminal 3 of the impedance matching circuit 1.

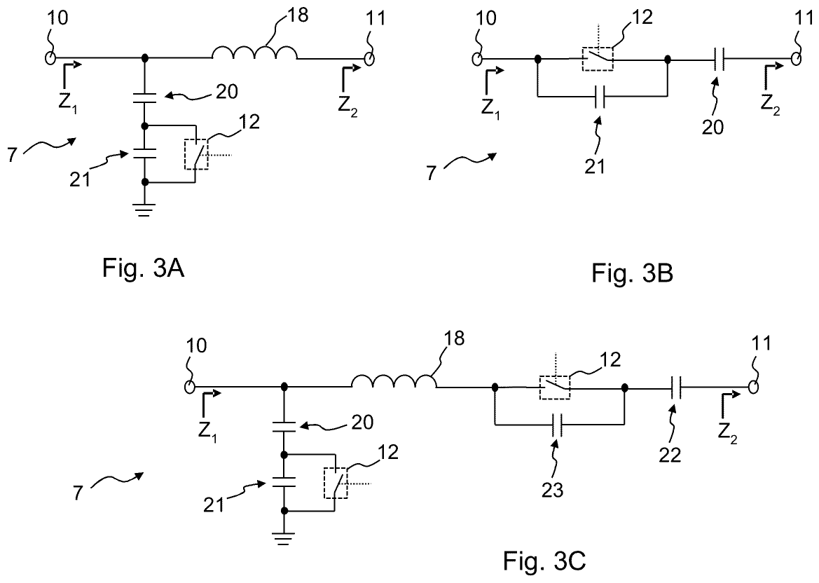

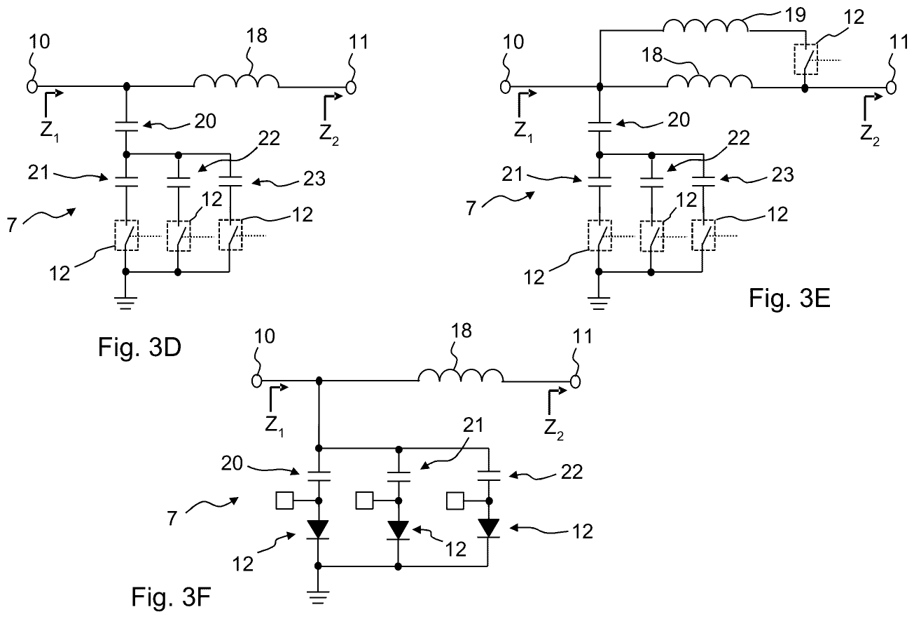

The second impedance matching unit 7 has at least one semiconductor switching element 12, as shown in FIGS. 3A to 3F and will be explained in more detail later. This at least one semiconductor switching element 12 of the second impedance matching unit 7 can be operated up to a maximum permissible voltage and up to a maximum permissible current. The first intermediate impedance Z₁, to which the first impedance matching unit 6 transforms the input impedance Z₀, is selected for a predetermined target input impedance such that:
a) the conductance of the first intermediate impedance Z₁ is greater than the conductance of the impedance that would arise at the input 10 of the second impedance matching unit 7 at the rated power P_{rated} of the impedance matching circuit 1 and the maximum permissible voltage of the at least one semiconductor switching element 12; and
b) the resistance of the first intermediate impedance Z₁ is greater than the resistance of the impedance that would arise at the input 10 of the second impedance matching unit 7 at the rated power P_{rated} and the maximum permissible current of the at least one semiconductor switching element 12.

The rated power P_{rated} of the impedance matching circuit 1 is preferably identical to the rated power P_{rated} of the HF power supply 101.

A transmission path for transmitting the HF signal runs between the input terminal 2 and the output terminal 3 of the impedance matching circuit 1. The first, second and third impedance matching units 6, 7, 8 are thereby arranged in the transmission path.

In the following figures, a possible structure of the first, second and third impedance matching units 6, 7, 8 of the impedance matching circuit 1 is explained in more detail.

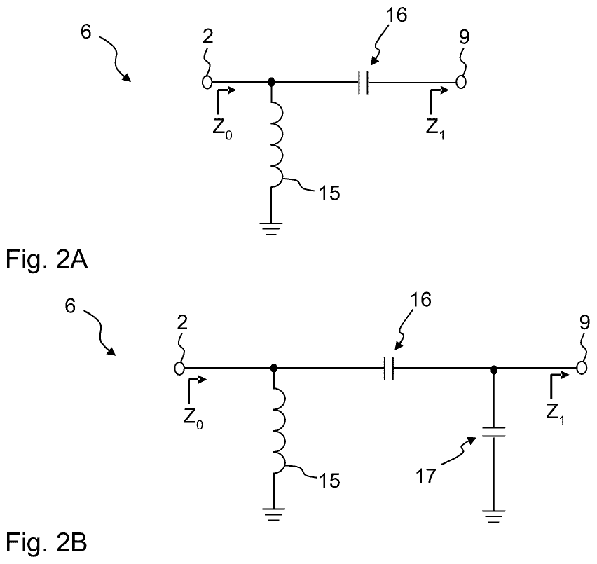

FIGS. 2A and 2B describe a possible structure of the first impedance matching unit 6. The first impedance matching unit 6 has a constant and thus unchanging transformation ratio during operation.

In FIG. 2A, the first impedance matching unit 6 comprises a coil 15 and a first capacitor 16. These are preferably configured as discrete components. The coil 15 connects the input terminal 2 to a reference ground. The first capacitor 16 connects the input terminal 2 to the output 9 of the first impedance matching unit 6. The first intermediate impedance Z₁ is also present at this output.

In FIG. 2B, the first impedance matching unit 6 also comprises a second capacitor 17. In contrast to FIG. 2A, the second capacitor 17 from FIG. 2B also connects the output 9 of the first impedance matching unit 6 to the reference ground.

FIGS. 3A, 3B, 3C, 3D, 3E, 3F describe a possible structure of the second impedance matching unit 7.

In FIG. 3A, the second impedance matching unit 7 comprises a first capacitor 20, a second capacitor 21, a first coil 18 and a semiconductor switching element 12. The first coil 18 connects the input 10 of the second impedance matching unit 7 to the output 11 of the second impedance matching unit 7. The first capacitor 20 and the second capacitor 21 are connected in series, wherein the first capacitor 20 is connected to the input 10 and the second capacitor 21 is connected to the reference ground. The semiconductor switching element 12 is arranged in parallel with the second capacitor 21. The semiconductor switching element 12 is preferably a transistor. If the semiconductor switching element 12 is conductive, the second capacitor 21 is not effective. The second capacitor 21 is bridged. If the semiconductor switching element 12 is blocked, an electrically effective series circuit consisting of the first capacitor 20 and the second capacitor 21 is present.

In FIG. 3B, the second impedance matching unit 7 comprises a first capacitor 20, a second capacitor 21 and a semiconductor switching element 12. The first capacitor 20 is connected to the output 11 of the second impedance matching unit 7. A parallel circuit consisting of the second capacitor 21 and the semiconductor switching element 12 is arranged in series with the first capacitor 20. This parallel circuit is also connected to the input 10 of the second impedance matching unit 7. If the semiconductor switching element 12 is conductive, only the first capacitor 20 between the input 10 and the output 11 is effective. The second capacitor 21 is bridged by the semiconductor switching element 12. If the semiconductor switching element 12 is blocked, the second capacitor 21 is electrically active and a series circuit consisting of the first capacitor 20 and the second capacitor 21 is formed between the input 10 and the output 11.

FIG. 3C shows a combination of the exemplary embodiments from FIGS. 3A and 3B. A first, second, third and fourth capacitor 20, 21, 22, 23 are provided. Furthermore, two semiconductor switching elements 12 and a first coil 18 are provided. The input 10 is connected to the reference ground via a series circuit. The series circuit comprises the following elements:
a) the first capacitor 20;

b) a parallel circuit consisting of the second capacitor 21 and the semiconductor switching element 12.

The input 10 is connected to the output 11 via further series circuit. The further series connection comprises the following elements:
a) the first coil 18;
b) a parallel circuit consisting of the fourth capacitor 23 and the semiconductor switching element 12;
c) the third capacitor 22.

FIG. 3D shows a further exemplary embodiment which is based on the exemplary embodiment of FIG. 3A. A first, second, third and fourth capacitor 20, 21, 22, 23 are provided. Furthermore, three semiconductor switching elements 12 and a first coil 18 are provided. The first coil 18 connects the input 10 to the output 11. The input 10 is also connected to the reference ground via a series circuit. The series circuit comprises the following elements:
a) the first capacitor 20;
b) a parallel circuit comprising three further series circuits, wherein the first further series circuit comprises the second capacitor 21 and a semiconductor switching element 12, wherein the second further series circuit comprises the third capacitor 22 and a semiconductor switching element 12 and wherein the third further series circuit comprises the fourth capacitor 23 and a semiconductor switching element 12.

If all three semiconductor switching elements 12 were blocked, the first capacitor 20 would not be connected to the reference ground. Each semiconductor switching element 12, when conducting, connects the first capacitor 20 to the reference ground via its second, third or fourth capacitor 21, 22, 23.

FIG. 3E shows a further exemplary embodiment which is based on the exemplary embodiment of FIG. 3D. A first, second, third and fourth capacitor 20, 21, 22, 23 are provided. Furthermore, three semiconductor switching elements 12, a first coil 18 and a second coil 19 are provided. The first coil 18 connects the input 10 to the output 11. A series circuit consisting of the second coil 19 and a semiconductor switching element 12 is arranged parallel to the first coil 18. When the semiconductor switching element 12 is conducting, the second coil is electrically connected in parallel with the first coil 18. In this case, the input 10 is connected to the output 11 via the parallel circuit consisting of the first and second coils 18, 19. If the semiconductor switching element 12 is blocked, no current flows through the second coil 19. The input 10 is only connected to the output 11 via the first coil 18. The input 10 is also connected to the reference ground via a series circuit. The series circuit comprises the following elements:
a) the first capacitor 20;
b) a parallel circuit comprising three further series circuits, wherein the first further series circuit comprises the second capacitor 21 and a semiconductor switching element 12, wherein the second further series circuit comprises the third capacitor 22 and a semiconductor switching element 12 and wherein the third further series circuit comprises the fourth capacitor 23 and a semiconductor switching element 12.

If all three semiconductor switching elements 12 were blocked, the first capacitor 20 would not be connected to the reference ground. Each semiconductor switching element 12, when conducting, connects the first capacitor 20 to the reference ground via its second, third or fourth capacitor 21, 22, 23.

In FIGS. 3A, 3B, 3C, 3D, 3E, the semiconductor switching elements 12 can be configured as transistors. FIG. 3F corresponds in structure to the embodiment in FIG. 3D. In contrast to FIG. 3D, the semiconductor switching element 12 is configured as a diode arrangement. The cathode side of the respective diodes is connected to the reference ground. A direct voltage can be applied to the anode side of the respective diodes 12, causing the respective diode to become conductive. The direct voltage can be applied individually to each of the respective diodes. This allows the diodes to be switched separately. The diodes are preferably PIN diodes.

The semiconductor switching elements 12 in FIGS. 3A to 3F can also comprise a mixture of transistors and diodes.

The control signal, in particular the direct voltage, for the semiconductor switching element 12 in the form of a transistor and/or a diode, can be generated by the control and/or detection device 105.

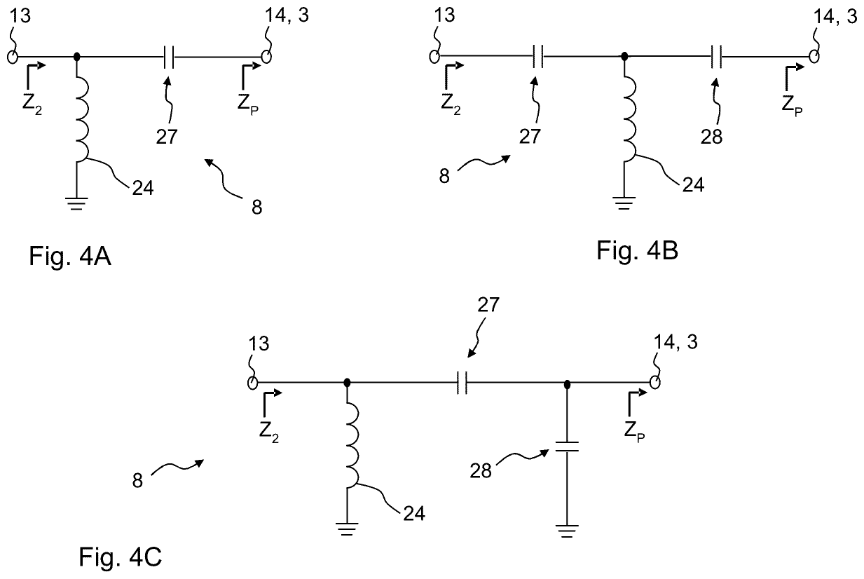

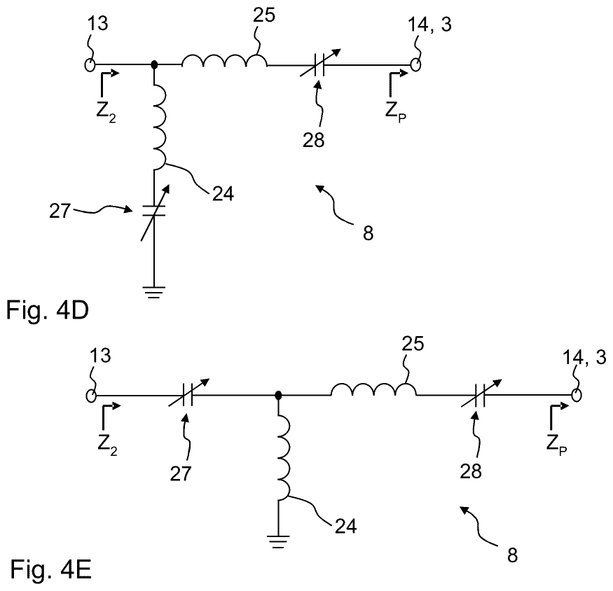

FIGS. 4A, 4B, 4C, 4D, 4E, 4F describe a possible structure of the third impedance matching unit 8.

In FIG. 4A, the third impedance matching unit 8 comprises a first capacitor 27 and a first coil 24. The first capacitor 27 and the first coil 24 are arranged in an L-circuit. The first coil 24 connects the input 13 of the third impedance matching unit 8 to a reference ground. The first capacitor 27 connects the input 13 to the output 14. The output 14 of the third impedance matching unit 8 can be directly connected to the output terminal 3 of the impedance matching circuit 1.

In FIG. 4B, the third impedance matching unit 8 comprises a first capacitor 27, a second capacitor 28 and a first coil 24. The first capacitor 27, the second capacitor 28 and the coil 24 are arranged in a T-circuit. The input 13 is connected to the output 14 via the first and second capacitors 27, 28, which are connected in series. The first coil 24 is arranged between the first capacitor 27 and the second capacitor 28 and establishes a connection to the reference ground. In this case, the input 13 is connected to the reference ground via the first capacitor 27 and the first coil 24. The output 14 is connected to the reference ground via the second capacitor 28 and the first coil 24.

In FIG. 4C, the third impedance matching unit 8 comprises a first capacitor 27, a second capacitor 28 and a first coil 24. The first capacitor 27, the second capacitor 28 and the coil 24 are arranged in a PI-circuit. The input 13 is connected to the reference ground via the first coil 24. The input 13 is also connected to the output 14 via the first capacitor 27. The output 14 is connected to the reference ground via the second capacitor 28.

In FIGS. 4A, 4B, 4C, the transformation ratio of the third impedance matching unit 8 cannot be changed during operation. In order to change the transformation ratio, the corresponding capacitors 27, 28 or the first coil 24 would have to be replaced by other capacitors or by another first coil with changed values.

In FIG. 4D, the third impedance matching unit 8 comprises a first capacitor 27, a second capacitor 28, a first coil 24 and a second coil 25. The input 13 is connected to the reference ground via a series circuit comprising the first coil 24 and the first capacitor 27. In this case, the first capacitor 27 is variable, in particular motorized for height adjustment. The input 13 is also connected to the output 14 via a series circuit comprising the second coil 25 and the second capacitor 28. In this case, the second capacitor 28 is variable, in particular motorized for height adjustment. In principle, only one of the two capacitors 27, 28 can be variable.

In FIG. 4E, the third impedance matching unit 8 comprises a first capacitor 27, a second capacitor 28, a first coil 24 and a second coil 25. The input 13 is connected to the reference ground via a series circuit comprising the first capacitor 27 and the first coil 24. The input 13 is also connected to the output 14 via a series circuit comprising the first capacitor 27, the second coil 25 and the second capacitor 28. In this case, the first capacitor 27, the second coil 25 and the second capacitor 28 are arranged in the signal transmission path between the input 13 and the output 14. The output 14 is therefore connected to the reference ground via a series circuit comprising the second capacitor 28, the second coil 25 and the first coil 24. In this case, the first capacitor 27 is variable, in particular motorized for height adjustment. In this case, the second capacitor 28 is also variable, in particular motorized for height adjustment. In principle, only one of the two capacitors 27, 28 can be variable.

A typical impedance matching circuit 1 is described, for example, in patent application DE 10 2023 104 942.9, filed on Feb. 28, 2023, entitled “Impedanzanpassungsschaltung, Plasmaprozessversorgungssystem und Plasmaprozesssystem,” which is hereby fully incorporated by reference into the present application.

In particular, the further impedance matching circuit (1) described in the said application can further develop the present impedance matching circuit 1 with individual or all of its features.

A typical plasma process system 9 is described, for example, in patent application DE 10 2023 104 948.8, filed on Feb. 28, 2023, entitled “Impedanzanpassungsschaltung, Plasmaprozessversorgungssystem und Plasmaprozesssystem,” which is hereby fully incorporated by reference into the present application. In particular, the second impedance matching unit (7, 7a-7f) described in the said application can be an embodiment of the second impedance matching unit 7 described here.

With the features described above, the number of components, such as semiconductor switching elements or reactances, e.g., coils and/or capacitors as well as capacitors and/or inductors, can be kept lower, thus achieving an even more compact design.

The present disclosure is not limited to the described exemplary embodiments. Within the scope of the present disclosure, all described and/or drawn features can be freely combined with one another.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. An impedance matching circuit for a plasma process system, for powers ≥500 W and frequencies in the range from 2 MHz to 100 MHz, wherein the impedance matching circuit is configured for a predetermined rated power, the impedance matching circuit comprising:
an input terminal configured to electrically connect the impedance matching circuit to a high frequency (HF) power supply;
an output terminal configured to electrically connect the impedance matching circuit to a consumer in the form of a plasma process chamber;
a first impedance matching unit which is electrically connected to the input terminal and configured to transform an input impedance at the input terminal to a first intermediate impedance, wherein a transformation ratio of the first impedance matching unit cannot be changed during operation;
a second impedance matching unit having at least one semiconductor switching element which is electrically connected at its input to the first impedance matching unit, and which is configured to transform the first intermediate impedance at its input to a second intermediate impedance at its output, wherein the transformation ratio is configured to be changed during operation by the at least one semiconductor switching element;
a third impedance matching unit which is electrically connected to the output of the second impedance matching unit and which is electrically connected with its output to the output terminal and which is configured to transform the second intermediate impedance at its input to an output impedance at the output terminal;
the at least one semiconductor switching element of the second impedance matching unit is configured to be operated up to a maximum permissible voltage and a maximum permissible current;
the first intermediate impedance, to which the first impedance matching unit transforms the input impedance, is selected for a predetermined target input impedance such that:
a) a conductance of the first intermediate impedance is greater than a conductance of the impedance that would arise at the input of the second impedance matching unit at the rated power of the impedance matching circuit and a maximum permissible voltage of the at least one semiconductor switching element; and
b) a resistance of the first intermediate impedance is greater than a resistance of an impedance that would arise at the input of the second impedance matching unit at the rated power of the impedance matching circuit and a maximum permissible current of the at least one semiconductor switching element.

2. The impedance matching circuit according to claim 1, wherein:
the first intermediate impedance is selected such that:
$${G}_{1} > {P}_{rated} / {U}_{max}^{2} ,$$
with
G₁=conductance of the first intermediate impedance,
P_{rated}=rated power of the impedance matching circuit, and
Uₘₐₓ=maximum voltage at the at least one semiconductor switching element; and
$${R}_{1} > {P}_{r a t e d} / {I}_{max}^{2} ,$$
with
R₁=resistance of the first intermediate impedance,
P_{rated}=rated power of the impedance matching circuit, and
Iₘₐₓ=maximum current at the at least one semiconductor switching element.

3. The impedance matching circuit according to claim 1, wherein the following feature:
the input impedance is substantially constant during operation of the impedance matching circuit and is equal to the predetermined target input impedance.

4. The impedance matching circuit according to claim 1, wherein:
the first intermediate impedance is closer on the Smith chart to the output impedance than to the input impedance; and/or
the second intermediate impedance is closer on the Smith chart to the output impedance than to the first intermediate impedance.

5. The impedance matching circuit according to claim 1, wherein:
the at least one semiconductor switching element of the second impedance matching unit is a transistor or a diode.

6. The impedance matching circuit according to claim 1, wherein:
the output impedance is configured to be determined by the consumer and is configured to be changed during operation, wherein the output impedance is configured to lie within a certain range on a Smith chart and wherein the at least one semiconductor switching element assumes different switching states for points of the output impedance that lie furthest apart within a specified range on the Smith chart.

7. The impedance matching circuit according to claim 1, wherein:
a transformation ratio of the third impedance matching unit cannot be changed during operation.

8. The impedance matching circuit according to claim 1, wherein:
the third impedance matching unit comprises at least one motor-adjustable capacitor, whereby the transformation ratio of the third impedance matching unit is configured to be changed during operation.

9. The impedance matching circuit according to claim 8, wherein:
the second intermediate impedance, to which the second impedance matching unit transforms the first intermediate impedance, is selected such that:
a) a conductance of the second intermediate impedance is greater than the conductance of the impedance that would arise at the rated power of the impedance matching circuit and a maximum voltage at the at least one motor-adjustable capacitor; and
b) a resistance of the second intermediate impedance is greater than the resistance of the impedance that would arise at the rated power of the impedance matching circuit and a maximum current at the at least one motor-adjustable capacitor.

10. The impedance matching circuit according to claim 9, wherein:
the second intermediate impedance is selected such that:
$${G}_{2} > {P}_{rated} / {U}_{max}^{2} ,$$
with
G₂=conductance of the second intermediate impedance,
P_{rated}=rated power of the impedance matching circuit, and
Uₘₐₓ=maximum voltage of the at least one motor-adjustable capacitor; and
$${R}_{2} > {P}_{r a t e d} / {I}_{max}^{2} ,$$
with
R₂=resistance of the second intermediate impedance,
P_{rated}=rated power of the impedance matching circuit, and
Iₘₐₓ=maximum current at the at least one motor-adjustable capacitor.

11. The impedance matching circuit according to claim 1, wherein:
the third impedance matching unit is free of a semiconductor switching element.

12. The impedance matching circuit according to claim 1, wherein:
the first impedance matching unit comprises at least one output, one coil and at least one first capacitor, each of which is configured as a discrete component;
the at least one coil connects the input terminal to a reference ground; and
the at least one first capacitor connects the input terminal of the impedance matching circuit to the output at which the first intermediate impedance is present.

13. The impedance matching circuit according to claim 11, wherein:
the first impedance matching unit comprises at least one second capacitor which is configured as a discrete component;
the at least one second capacitor connects the output of the first impedance matching unit to a reference ground.

14. The impedance matching circuit according to claim 1, wherein:
the second impedance matching unit comprises at least one coil, at least one first capacitor and at least one further capacitor, each of which is configured as a discrete component;
the first intermediate impedance is present at an input of the second impedance matching unit, and the second intermediate impedance is present at an output of the second impedance matching unit;
the at least one coil is arranged in a transmission path connecting the input to the output; and
the at least one semiconductor switching element is configured:
a) to effectively electrically connect the transmission path to a reference ground via the at least one first capacitor; and/or
b) to effectively connect the at least one further capacitor in series in the transmission path.

15. The impedance matching circuit according to claim 14, wherein:
the second impedance matching unit comprises a plurality of semiconductor switching elements and a plurality of capacitors;
the plurality of semiconductor switching elements are configured:
a) to electrically connect the transmission path to a reference ground via each of the plurality of capacitors, wherein a semiconductor switching element is arranged in series with each of the plurality of capacitors and wherein each of the plurality of capacitors with its respective semiconductor switching element is arranged in parallel with other capacitors of the plurality of capacitors with their respective semiconductor switching elements, whereby a plurality of transformation ratios are configured to be set; and/or
b) to effectively connect at least one of the plurality of capacitors and/or one coil to the transmission path, wherein one semiconductor switching element is arranged in series with or parallel to the at least one of the plurality of capacitors or the one coil, whereby a multitude of transformation ratios are configured to be set.

16. The impedance matching circuit according to claim 1, wherein:
the third impedance matching unit comprises at least one coil and at least one capacitor, each of which is configured as a discrete component;
the third impedance matching unit comprises an input, the output terminal and a transmission path, wherein the transmission path electrically connects the input to the output terminal;
the second intermediate impedance is present at the input;
the at least one coil connects the transmission path to a reference ground.

17. The impedance matching circuit according to claim 16, wherein:
the at least one coil is connected to the input directly or via the at least one capacitor; and/or
the at least one coil is connected to the output terminal directly or via the at least one capacitor and/or a further coil.

18. The impedance matching circuit according to claim 1, wherein:
the at least one semiconductor switching element is configured to be cooled by a fluid.

19. A plasma process system having the impedance matching circuit according to claim 1, wherein:
an HF power supply and at least one consumer in the form of a plasma process chamber are provided, wherein the HF power supply is configured to supply an HF signal with the rated power;
the HF power supply is connected to the input terminal of the impedance matching circuit; and
the output terminal of the impedance matching circuit is connected to the at least one consumer.

20. The plasma process system according to claim 19, wherein:
a measuring unit is arranged between the HF power supply and the impedance matching circuit;
the measuring unit comprises at least one directional coupler or a combination of a current sensor and a voltage sensor;
a control and/or detection device is provided, wherein the control and/or detection device is configured to receive measured values, such as a power transmitted into the impedance matching circuit, from the measuring unit, which describe input variables present at the input terminal of the impedance matching circuit; and
the control and/or detection device is configured to control the at least one semiconductor switching element based on the measured values such that a desired plasma is generated.
